(19) United States
(12) Patent Application Publication
(10) Pub. No.: US 2008/0171523 A1
(43) Pub. Date: Jul. 17, 2008

(54) Power Amplifier Bias Control

(75) Inventors: William David Anderson, Chapel Hill, NC (US); David Ryan Story, Holly Springs, NC (US); Michael Alan Oakley, Durham, NC (US)

Correspondence Address: COATS & BENNETT/SONY ERICSSON, 1400 CRESCENT GREEN, SUITE 300, CARY, NC, 27511, US

(73) Assignee: Sony Ericsson Mobile Communications AB, Lund (SE)

(21) Appl. No.: 11/613,392

(22) Filed: Dec. 20, 2006

(51) Int. Cl. H04B 1/04; H03G 3/20

(52) U.S. Cl. 455/127.1; 330/136

(57) ABSTRACT

A power amplifier circuit for a mobile terminal controls the bias voltage depending on the modulation of the input signal. The power amplifier circuit includes a power amplifier control circuit configured to control power amplifier bias for a first input signal modulation using calibrated bias control values corresponding to a range of transmit power levels, and to control power amplifier bias for said second input signal modulation using adjusted bias control values obtained by adding bias offsets to said calibrated bias control values.

### BACKGROUND

The present invention relates generally to power amplifiers for mobile devices, and more particularly, to a method and apparatus for controlling bias voltage of power amplifiers.

Mobile terminals typically operate on battery power and thus have significant constraints on overall operating power. As the size of mobile terminals decrease in response to consumer demands for convenience and portability, so too does the size of included batteries. At the same time, consumers expect longer talk times and longer battery life. To meet these conflicting consumer demands, manufacturers of mobile terminals are constantly looking for ways to improve the power efficiency of mobile terminals.

The RF power amplifier of a mobile terminal represents one of the greatest drains on battery power. The ratio of output RF power to input DC power establishes the power amplifier's efficiency rating. In the case of a linear power amplifier, the efficiency of the power amplifier increases as the amplifier's output power moves upward through the linear amplification range, and reaches its maximum at a defined point in the amplifier's saturated mode of operation. However, the distortion produced when operating in a saturated mode may be unacceptable. The trade-off between efficiency and linearity of the amplifier is a primary concern in the power amplifier design

Modern mobile terminals use a variety of different modulation schemes and some require more linearity than others. For example, a WCDMA terminal may require greater linearity when transmitting on the High Speed Dedicated Physical Control Channel (HS-DPCCH) in the HSDPA mode than it does for normal voice communications due to the different signal modulations. When transmitting on the HS-DPCCH, the modulation produces a large peak-to-average ratio, while the modulation for normal voice communications has a lower peak-to-average ratio. Current practice is to select operating points for the power amplifier for the worst case modulation. For example, one of the worst case modulations is with β_{C}/β_{D}= 12/15, and β_{HS}/β_{C}= 30/15. If the bias voltage for a WCDMA terminal is selected to satisfy ACLR requirements when transmitting on the HS-DPCCH, then the power amplifier will have excessive margins when transmitting in normal voice mode.

### SUMMARY

The present invention provides a method and apparatus for controlling the bias of a power amplifier depending on the modulation of the transmitted signal to improve the overall efficiency of the power amplifier across a range of operating conditions. According to one exemplary embodiment, a power amplifier control circuit controls power amplifier bias for a first input signal modulation using a set of calibrated bias control values corresponding to a range of transmit power levels. For a second input signal modulation, the power amplifier control circuit adjusts the calibrated bias control values by adding bias offsets to the calibrated bias control values, and controls the power amplifier bias using the adjusted bias control values. The present invention can be implemented, if desired, using a single lookup table containing the calibrated bias control values.

By varying the bias voltage for different modulation schemes, an appropriate trade-off between efficiency and linearity can be made for each modulation scheme used. Consequently, the overall efficiency of the power amplifier is improved.

### BRIEF DESCRIPTION OF THE DRAWINGS

FIG. 1 illustrates an exemplary amplifier circuit according to one exemplary embodiment of the invention.

FIG. 2 illustrates an exemplary mobile terminal according to one embodiment of the invention.

FIG. 3 illustrates exemplary control logic for a power amplifier control circuit.

FIG. 4 is a graph showing the bias voltage for a HSDPA mode and voice mode respectively for one exemplary embodiment of the invention.

FIG. 5 is a graph comparing the efficiency of the power amplifier according to the present invention to a prior art power amplifier.

### DETAILED DESCRIPTION

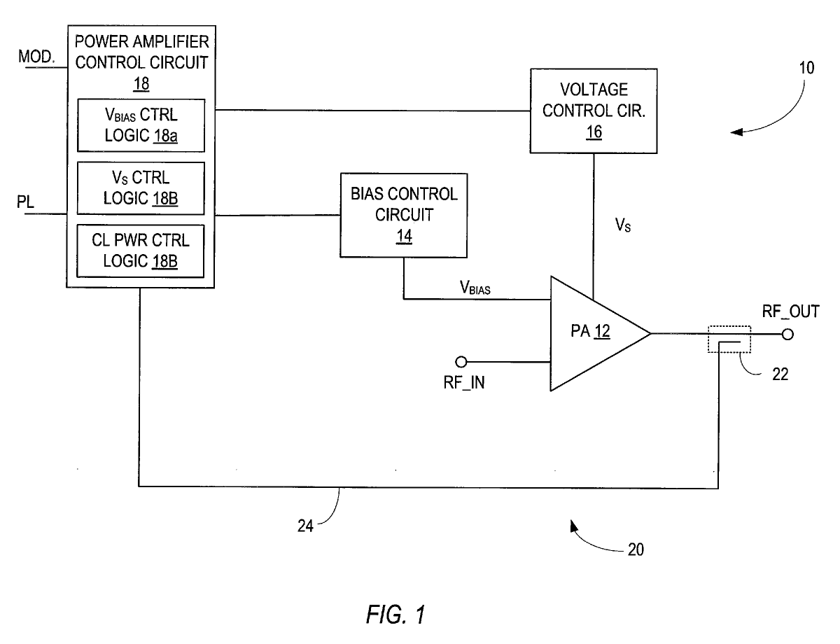

Referring now to the drawings, FIG. 1 illustrates an exemplary power amplifier circuit 10 according to one embodiment of the invention. The primary function of the power amplifier circuit 10 is to amplify a radio frequency input signal (RF_IN) to generate an amplified output signal (RF_OUT) for a mobile terminal, such as a cellular phone, PDA, or laptop computer. The power amplifier circuit 10 comprises a power amplifier 12, a bias control circuit 14, a voltage control circuit 16, a power amplifier control circuit 18, and a feedback control loop 20.

The power amplifier 12 may comprise a linear power amplifier. The power amplifier 12 amplifies the input signal RF_IN to produce the amplified output signal RF_OUT. The gain of the power amplifier 12 is the ratio of the input signal RF_IN to the output signal RF_OUT. The efficiency of the power amplifier 12 improves as the power amplifier 12 approaches saturation. However, the output signal RF_OUT becomes more distorted as the power amplifier 12 nears saturation.

The bias control circuit 14 connects to a bias input of the power amplifier 12 and outputs a bias voltage V_{BIAS} that determines the operating point and idle current of the power amplifier 12. The bias control circuit 14 receives a bias control value from the power amplifier control circuit 18 and adjusts the bias voltage V_{BIAS} accordingly. In general, the bias voltage V_{BIAS} applied to the power amplifier 12 will vary depending on the current transmit power level T_{P} of the power amplifier 12, and on the modulation of the input signal. For some input signal modulations, it is desirable to operate the power amplifier 12 at an operating point near saturation to improve efficiency. However, for some input signal modulations, the distortions may not be tolerable and it may be preferred to operate the power amplifier at an operating point in a more linear range.

The voltage control circuit 16 connects to a supply input of the power amplifier and controls the supply voltage V_{S} to the power amplifier 12. The voltage control circuit 16 controls the supply voltage V_{S} in response to voltage control signal from the power amplifier control circuit 18. In general, the supply voltage V_{S} increases with increasing transmit power T_{P}.

The power amplifier control circuit 18 controls the operation of the power amplifier 12. The power amplifier control circuit 18 may comprise a dedicated microprocessor or microcontroller, or may be part of the baseband processing circuit of the mobile terminal. The main functions of the power amplifier control circuit 18 are to control the bias voltage V_{BIAS} and supply voltage V_{S} provided to the power amplifier 12, and to perform closed loop power control of the output signal RF_OUT.

The power amplifier control circuit 18 includes bias voltage control logic 18a, supply voltage control logic 18b, and closed loop power control logic 18c. The bias voltage control logic 18a generates a bias control value (CV_{B}) based on the current transmit power level T_{P} of the mobile terminal and the modulation of the input signal. The bias control value CV_{B} is output to the bias control circuit 14. The supply voltage control logic 18b generates a voltage control value (CV_{V}) based on the current transmit power level T_{P}. The voltage control value CV_{V} is output to the voltage control circuit 16. The closed loop power control logic 18c performs closed loop power control to correct for any errors in the measured output power of the power amplifier 12.

The feedback control loop 20 comprises a power coupler 22 to sense the output power of the output signal RF_OUT and to provide a feedback signal on line 24 to the power amplifier control circuit 18 for closed loop power control. The power amplifier control circuit 18 compares the power of the output signal RF_OUT to a desired target power value, generates an error signal proportional to the difference, and uses the error signal to adjust the drive level to the power amplifier 12 to correct for any error in the power level of the output signal RF_OUT.

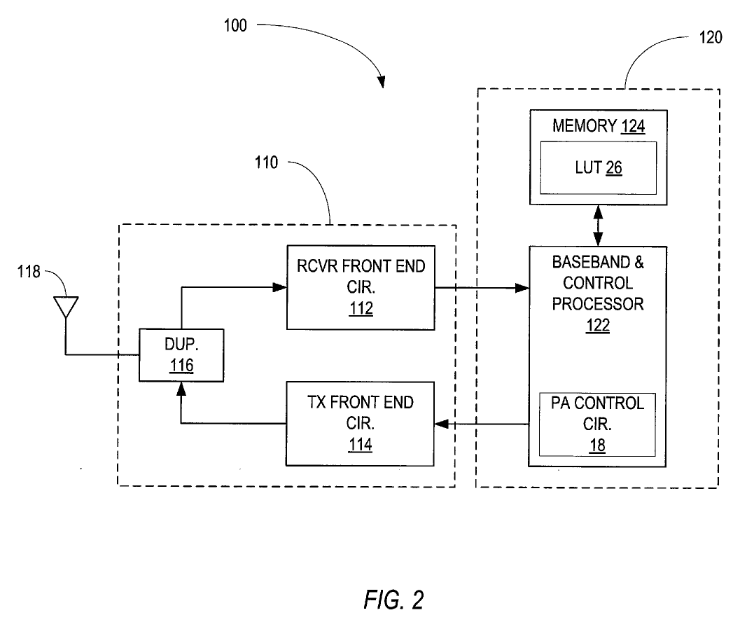

FIG. 2 illustrates an exemplary mobile terminal 100 in which the power amplifier circuit 10 may be used. The mobile terminal 100 may operate according to any known communication standard. In this example, it is assumed that the mobile terminal 100 is a Wideband Code Division Multiple Access (WCDMA) terminal.

The mobile terminal 100 comprises a transceiver section 110 and a processing and control section 120. The transceiver section 110 includes a receiver front end circuit 112 and a transmitter front end circuit 114 coupled by a duplexer 116 to a shared antenna 118. Those skilled in the art will appreciate, however, that the receiver front end circuit 112 and transmitter front end circuit 114 may use separate antennas 118.

The transmitter front end circuit 114 includes the amplifier circuit 10 (excepting the power amplifier control circuit 18) as described above. The processing and control section 120 includes a baseband and control processor 122 and memory 124. Baseband and control processor 122 processes signals transmitted and received by the mobile terminal 100, and controls the overall operation of the mobile terminal 100. The baseband and control processor 122 includes the power amplifier control circuit 18 as described above. The baseband and control processor 122 may comprise one or more processors, hardware processing circuits, or a combination thereof.

In a WCDMA terminal, the mobile terminal 100 may use a variety of different modulation schemes. For example, one type of modulation may be used for normal voice communications and a different type of modulation may be used for transmitting on the High Speed Dedicated Physical Control Channel (HS-DPCCH) when the mobile terminal 100 is in the High Speed Downlink Packet Access (HSDPA) mode. The peak-to-average-ratio of the transmitted signal will vary depending on the type of modulation used. In general, the bias voltage V_{BIAS} can be adjusted downward when the modulation scheme produces a low peak-to-average ratio, and adjusted upward when the modulation scheme produces a high peak-to-average ratio. Adjusting the bias voltage V_{BIAS} downward improves efficiency of the power amplifier 12 at the cost of greater distortion, while adjusting the bias voltage V_{BIAS} upward improves linearity of the power amplifier 12 at the cost of reduced efficiency.

According to the present invention, the power amplifier control circuit 18 takes the modulation of the input signal into account to control the bias voltage V_{BIAS} applied to the power amplifier 12. By adjusting the bias voltage V_{BIAS}, the power amplifier control circuit 18 can select an operating point that appropriately balances the desire for improved efficiency with the need for greater linearity. For example, a mobile terminal 100 transmitting on the HS-DPCCH requires greater linearity than normal voice communications to meet Adjacent Channel Leakage Power Ratio (ACLR) requirements. In general, greater linearity means reduced efficiency. For normal voice communications, on the other hand, the modulation used will have a lower peak-to-average ratio and thus a higher ACLR margin. In this case, the bias voltage V_{BIAS} can be decreased to improve the efficiency of the power amplifier 12.

In one exemplary embodiment, bias control values for a range of transmit power levels are stored in a look-up table 126 in memory 124. The power amplifier control circuit 18 is programmed to determine the current transmit power level, look up the corresponding bias control value in look-up table 126, and output the bias control value or other control signal derived therefrom to the bias control circuit 14. A different look-up table 126 for each different modulation scheme could be stored in memory. Switching between different tables for different modulation schemes, however, may not be desirable.

According to one exemplary embodiment, a set of calibrated bias control values associated with a first modulation scheme is stored in a look-up table 126 in memory 124. The calibrated bias control values are used to control the bias voltage V_{BIAS} of the power amplifier 12 when the first modulation scheme is used. For a second modulation scheme, the bias control values for different transmit power levels may be computed by adding bias offsets to the corresponding bias control values for the first modulation scheme stored in look-up table 126. Different bias offsets may be applied based on the transmit power level. The bias offsets may be stored in a separate lookup table in memory 124, or may be incorporated into the program code of the power amplifier control circuit 18. Alternatively, the power amplifier control circuit 18 may include program code to calculate the bias offset based on current conditions that change over time.

To illustrate the invention, consider a mobile terminal 100 that uses a first modulation for normal voice communications and a second modulation for transmitting on the HS-DPCCH. The mobile terminal 100 stores a set of calibrated bias control values for normal voice communications in the look-up table 126 in memory 124. When engaged in normal voice communications, the power amplifier control circuit 18 uses the calibrated bias control values stored in memory 124. When the mobile terminal 100 transmits on the HS-DPCCH, the power amplifier control circuit 18 adjusts the calibrated bias control value stored in memory by adding bias offsets to the calibrated bias control values. These adjusted bias control values are used to control the bias voltage V_{BIAS} to the power amplifier 12.

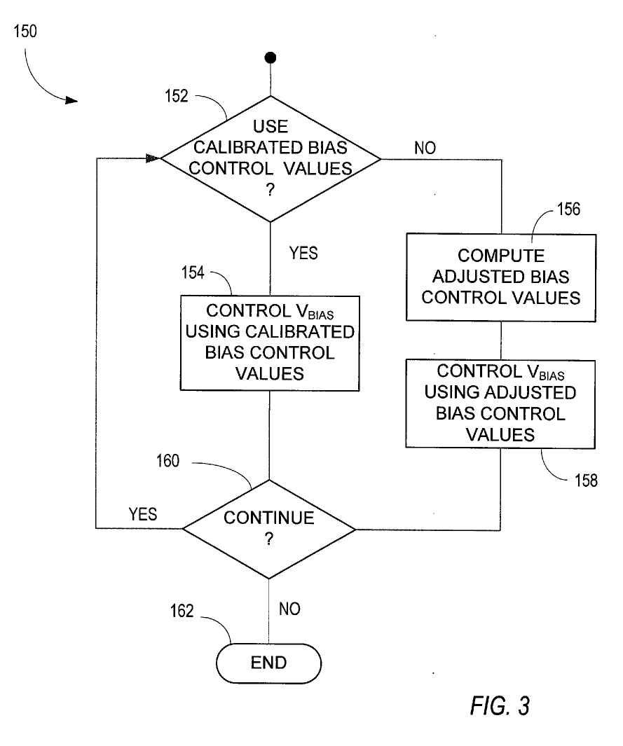

FIG. 3 is a flow diagram illustrating an exemplary method 150 implemented by the power amplifier control circuit 18 for controlling the bias voltage V_{BIAS} of the power amplifier 12. The power amplifier control circuit 18 receives two control inputs: one indicating the current modulation or operating mode (MOD) and one indicating the current transmit power level (PL) of the mobile terminal 100. The power amplifier control circuit 18 uses the control inputs to determine the control values for the bias voltage V_{BIAS} and supply voltage V_{S}. With respect to the bias voltage V_{BIAS}, the power amplifier control circuit 18 determines whether to use the calibrated bias control values stored in memory (block 152) based on the MOD input. For a first input signal modulation, the power amplifier control circuit 18 controls the bias voltage V_{BIAS} of the power amplifier 12 using the calibrated bias control values stored in memory (block 154). In this case, the power amplifier control circuit 18 uses the PL input to look up the corresponding bias control value. For a second input signal modulation, the power amplifier control circuit 18 computes adjusted bias control values (block 156) and controls the bias voltage of the power amplifier 12 using the adjusted bias control values (block 158). In this case, the power amplifier control circuit 18 uses the PL input to look up the calibrated bias control value and adds a bias offset to the calibrated bias control value to obtain the adjusted bias control value. The adjusted bias control value is used to control the bias voltage V_{BIAS} of the power amplifier 12. The bias control routine continues (block 160) while the mobile terminal 100 is transmitting and ends (block 162) when the mobile terminal 100 ceases transmission.

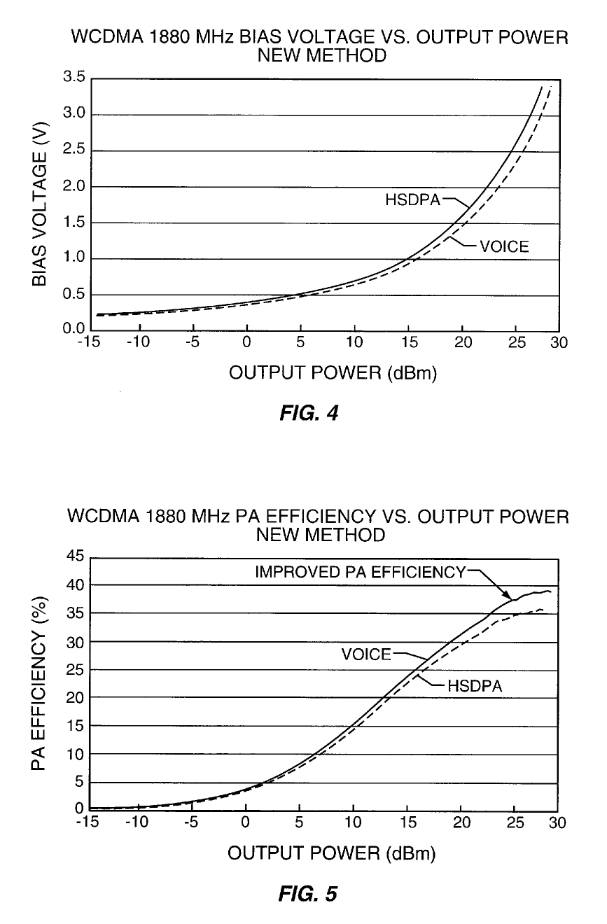

FIG. 4 is a graph illustrating the relation between the bias voltage and the output power level for normal voice mode and when transmitting on the HS-DPCCH in the HSDPA mode. As shown in FIG. 4, the bias voltage for normal voice communications is lower than the bias voltage when transmitting on the HS-DPCCH, particularly at high output powers.

FIG. 5 illustrates the improvement in efficiency that may be obtained. As seen in FIG. 5, there is a significant improvement in the efficiency of the power amplifier 12 at the high output powers. This improvement in efficiency equates to less power consumption and longer battery life for the mobile terminal 100.

Those skilled in the art will recognize the using the adjusted bias control values will cause a change in the gain of the power amplifier 12. Consequently, the output power and step sizes of the power amplifier 12 may not be exactly correct. Such error can be avoided or reduced by including a feedback loop 20 in the amplifier circuit 10. Power coupler 22 detects the current output power level of the power amplifier 12 and generates a feedback signal on line 24 indicative of the current output power of the power amplifier 12. The feedback signal is applied to the power amplifier control circuit 18. The supply voltage control logic 18b in the power amplifier control circuit 18 compares the measured output power of the power amplifier 12 to a desired target power level and determines an error, if any, in the output power of the power amplifier 12. If there is an error, the power amplifier control circuit 18 adds a correction value to the voltage control signal value to make appropriate correction in the output power of the power amplifier 12.

The present invention may, of course, be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of controlling bias voltage of a power amplifier, said method comprising:
controlling power amplifier bias for a first input signal modulation using calibrated bias control values corresponding to a range of transmit power levels; and
controlling power amplifier bias for said second input signal modulation using adjusted bias control values obtained by adding bias offsets to said calibrated bias control values.

2. The method of claim 1 wherein said bias offsets vary depending on a current power level of said power amplifier.

3. The method of claim 1 further comprising detecting an output power of said power amplifier, comparing said output power to a desired target output power, and controlling said power amplifier based on said comparison to maintain said output power at said target output power.

4. The method of claim 1 wherein said first bias control values are stored in a lookup table in memory.

5. A power amplifier circuit for a mobile terminal comprising:
a power amplifier;
a bias control circuit for generating a bias voltage for said power amplifier responsive to a bias control value; and
a power amplifier control circuit connected to said bias voltage control circuit for generating bias control values to control the bias voltage output by said bias voltage control circuit, said power amplifier control circuit configured to:
output calibrated bias control values corresponding to a range of transmit power levels for a first input signal modulation;
adjust said calibrated bias control values for a second input signal modulation by adding bias offsets to said calibrated bias control values; and
output said adjusted bias control values for said second input signal modulation.

6. The power amplifier circuit of claim 5 wherein said bias offsets vary depending on a current power level of said power amplifier.

7. The power amplifier circuit of claim 5 wherein said first bias control values are stored in a lookup table in memory.

8. The power amplifier circuit of claim 5 further comprising a supply voltage control circuit to apply a supply voltage to the power amplifier, wherein the power amplifier control circuit generates a control signal to control the supply voltage applied by the supply voltage control circuit to the power amplifier.

9. The power amplifier circuit of claim 8 wherein the power amplifier control circuit is operative to:
detect an output power of said power amplifier;
compare said output power to a desired target output power; and
control said supply based on said comparison to maintain said output power at said target output power.

10. A mobile terminal comprising:
a receiver;
a transmitter including a power amplifier and a bias voltage control circuit; and
a power amplifier control circuit connected to said bias voltage control circuit for generating bias control values to control the bias voltage output by said bias voltage control circuit, said power amplifier control circuit configured to:
output calibrated bias control values corresponding to a range of transmit power levels for a first input signal modulation to said bias control circuit;
adjust said calibrated bias control values for a second input signal modulation by adding bias offsets to said calibrated bias control values; and
output said adjusted bias control values for said second input signal modulation.

11. The mobile terminal of claim 10 wherein said bias offsets vary depending on a current power level of said power amplifier.

12. The mobile terminal of claim 10 wherein said first bias control values are stored in a lookup table in memory.

13. The mobile terminal of claim 10 further comprising a supply voltage control circuit to apply a supply voltage to the power amplifier, wherein the power amplifier control circuit generates a control signal to control the supply voltage applied by the supply voltage control circuit to the power amplifier.

14. The mobile terminal of claim 13 wherein the power amplifier control circuit is operative to:
detect an output power of said power amplifier;
compare said output power to a desired target output power; and
control said power amplifier based on said comparison to maintain said output power at said target output power.
